(19) United States
(12) Patent Application Publication
(10) Pub. No.: US 2026/0143790 A1
(43) Pub. Date: May 21, 2026

(54) SEMICONDUCTOR APPARATUS

(71) Applicant: FUJI ELECTRIC CO., LTD., Kanagawa (JP)

(72) Inventor: Yasuyuki HOSHI, Matsumoto-city (JP)

(21) Appl. No.: 19/334,927

(22) Filed: Sep. 21, 2025

(30) Foreign Application Priority Data
Nov. 18, 2024 (JP) 2024-200871

(51) Int. Cl. H10D 84/00; H10D 1/40; H10D 12/00; H10D 12/01; H10D 62/10; H10D 62/60; H10D 62/832; H10D 62/85; H10D 64/23

(52) U.S. Cl. CPC H10D 84/161; H10D 1/40; H10D 12/481; H10D 62/126; H10D 62/60; H10D 62/8325; H10D 62/8503; H10D 64/2527; H10D 12/038; H10D 12/415

(57) ABSTRACT

Provided is a semiconductor apparatus comprising a semiconductor substrate, and an additional layer provided on a front surface of the semiconductor substrate, including: a drift region of a first conductivity type provided in the semiconductor substrate; a base region of a second conductivity type provided above the drift region in the semiconductor substrate; a gate trench portion provided on an upper surface of the additional layer; an emitter region of the first conductivity type that is provided above the base region and is in contact with the gate trench portion; and a conductive trench contact portion provided from the upper surface of the additional layer to a position deeper than an upper end of the base region, wherein the emitter region includes: a contact emitter portion provided on the upper surface of the additional layer; a resistance emitter portion provided in the additional layer; and an additional emitter portion.

The contents of the following patent application(s) are incorporated herein by reference:
NO. 2024-200871 filed in JP on Nov. 18, 2024.

### BACKGROUND

### 1. Technical Field

The present invention relates to a semiconductor apparatus.

### 2. Related Art

In the prior art, there is known a technique for, in a semiconductor apparatus such as an Insulated Gate Bipolar Transistor (IGBT), changing, for example, arrangement of emitter regions and adjusting characteristics (see Patent Documents 1 to 3, for example).

Patent Document 1: Japanese Patent Application Publication No. 2008-91491

Patent Document 2: Japanese Patent Application Publication No. H10-173170

Patent Document 3: Japanese Patent Application Publication No. H9-283755

### BRIEF DESCRIPTION OF THE DRAWINGS

FIG. 1 is a top view showing an example of a semiconductor apparatus 100.

FIG. 2 is an example of an enlarged view of a region D in FIG. 1.

FIG. 3 illustrates one example of a cross section taken along a line a-a in FIG. 2.

FIG. 4 illustrates another example of a cross section taken along a line a-a in FIG. 2.

FIG. 5 is an example of an I-V curve that indicates a relationship between a collector current and an ON voltage.

FIG. 6 illustrates another example of a cross section taken along a line a-a in FIG. 2.

FIG. 7 illustrates another example of a cross section taken along a line a-a in FIG. 2.

FIG. 8 illustrates some steps in a fabrication method of the semiconductor apparatus 100.

FIG. 9 illustrates variants of a cross section taken along a line a-a in FIG. 2.

### DESCRIPTION OF EXEMPLARY EMBODIMENTS

Hereinafter, the present invention will be described through embodiments of the invention, but the following embodiments do not limit the invention according to claims. In addition, not all of the combinations of features described in the embodiments are essential to the solving means of the invention.

In the present specification, one side in a direction parallel to a depth direction of a semiconductor substrate is referred to as ‘upper’ or ‘front’ and the other side is referred to as ‘lower’ or ‘rear’. From two principal surfaces of a substrate, a layer or another member, one surface is referred to as an upper surface or a front surface, and the other surface is referred to as a lower surface or a back surface. The “upper”, “lower”, “front”, and “back” directions are not limited to a gravitational direction or a direction when the semiconductor apparatus is implemented.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate the height direction with respect to the ground. Note that a +Z axis direction and a −Z axis direction are directions opposite to each other. When the Z axis direction is described without describing the signs, it means that the direction is parallel to the +Z axis and the −Z axis.

In the present specification, orthogonal axes parallel to the front surface and the back surface of the semiconductor substrate are referred to as the X axis and the Y axis. In addition, an axis perpendicular to the front surface and the back surface of the semiconductor substrate is referred to as the Z axis. In the present specification, the direction of the Z axis may be referred to as the depth direction. In addition, in the present specification, a direction parallel to the front surface and the back surface of the semiconductor substrate may be referred to as a horizontal direction, including an X axis direction and a Y axis direction.

A region from the center in the depth direction of the semiconductor substrate to the front surface of the semiconductor substrate may be referred to as a front surface side. Similarly, a region from the center in the depth direction of the semiconductor substrate to the back surface of the semiconductor substrate may be referred to as a back surface side.

In the present specification, a case where a term such as “same” or “equal” is mentioned may include a case where an error due to a variation in manufacturing or the like is included. The error is, for example, within 10%.

In the present specification, a conductivity type of doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor presenting a conductivity type of the N type, or a semiconductor presenting conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is N_{D} and the acceptor concentration is N_{A}, the net doping concentration at any position is given as N_{D}-N_{A}. In the present specification, the net doping concentration may be simply referred to as the doping concentration.

The donor has a function of supplying electrons to a semiconductor. The acceptor has a function of receiving electrons from the semiconductor. The donor and the acceptor are not limited to the impurities themselves. For example, a VOH defect in which a vacancy (V), oxygen (O), and hydrogen (H) present in the semiconductor are attached together functions as the donor which supplies the electrons. In the present specification, the VOH defect may be referred to as a hydrogen donor.

In the present specification, a description of a P+ type or an N+ type means a higher doping concentration than that of the P type or the N type, and a description of a P− type or an N− type means a lower doping concentration than that of the P type or the N type. In the present specification, a unit system is the SI base unit system unless otherwise noted. Although a unit of length may be indicated by cm, it may be converted to meters (m) before calculations.

A chemical concentration in the present specification refers to an atomic density of an impurity measured regardless of an electrical activation state. The chemical concentration (an atomic density) can be measured by, for example, secondary ion mass spectrometry (SIMS). The net doping concentration described above can be measured by capacitance-voltage profiling (CV profiling). Further, a carrier concentration measured by spreading resistance profiling (SRP method) may be set as the net doping concentration. The carrier concentration measured by the CV profiling or the SRP method may be a value in a thermal equilibrium state. Further, in a region of the N type, the donor concentration is sufficiently higher than the acceptor concentration, and thus the carrier concentration of the region may be set as the donor concentration. Similarly, in a region of the P type, the carrier concentration of the region may be set as the acceptor concentration. In the present specification, the doping concentration of the N type region may be referred to as the donor concentration, and the doping concentration of the P type region may be referred to as the acceptor concentration.

When a concentration distribution of the donor, acceptor, or net doping has a peak in a region, a value of the peak may be set as the concentration of the donor, acceptor, or net doping in the region. In a case where the concentration of the donor, acceptor or net doping is substantially uniform in a region, or the like, an average value of the concentration of the donor, acceptor or net doping in the region may be set as the concentration of the donor, acceptor or net doping. In the present specification, atoms/cm³ or /cm³ is used to indicate a concentration per unit volume. This unit is used for a concentration of a donor or an acceptor in a semiconductor substrate, or a chemical concentration. A notation of atoms may be omitted.

The carrier concentration measured by the SRP method may be lower than the concentration of the donor or the acceptor. In a range where a current flows when a spreading resistance is measured, carrier mobility of the semiconductor substrate may be lower than a value in a crystalline state. The reduction in carrier mobility occurs when carriers are scattered due to disorder (disorder) of a crystal structure due to a lattice defect or the like.

The concentration of the donor or the acceptor calculated from the carrier concentration measured by the CV profiling or the SRP method may be lower than a chemical concentration of an element indicating the donor or the acceptor. As an example, in a silicon semiconductor, a donor concentration of phosphorous or arsenic serving as a donor, or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen. Each concentration in the present specification may be a value at room temperature. As an example, a value at 300 K (Kelvin) (substantially 26.9 degrees C.) may be used for a value at room temperature.

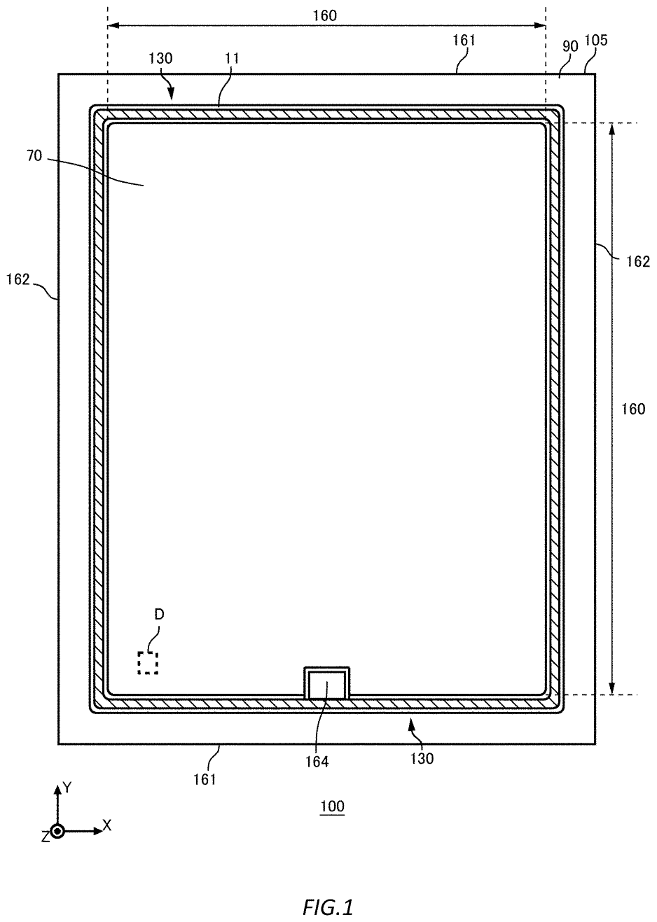

FIG. 1 is a top view showing an example of a semiconductor apparatus 100. The semiconductor apparatus 100 includes a semiconductor layer 105. The semiconductor layer 105 is a region in which a main current such as a collector current, a drain current or an anode-cathode current flows when the semiconductor apparatus 100 operates. FIG. 1 shows a position at which each member is projected on an upper surface of a semiconductor layer 105. FIG. 1 shows merely some members of the semiconductor apparatus 100, and omits illustrations of some members.

The semiconductor layer 105 includes the semiconductor substrate 10. The semiconductor substrate 10 is a substrate which is formed of a semiconductor material. Although the semiconductor substrate 10 is a silicon substrate by way of example, the material of the semiconductor substrate 10 is not limited to silicon. The semiconductor substrate 10 may include either of SiC or Gan of a wide band gap.

The semiconductor layer 105 has a first end side 161 and a second end side 162 in a top view. As merely referred to as the top plan view in the specification, it means that an upper surface side of the semiconductor layer 105 is viewed from above. The semiconductor layer 105 of this example has two sets of first end sides 161 opposite to each other in the top plan view. In addition, the semiconductor substrate 10 of the present example has two sets of second end sides 162 facing each other in a top view. In FIG. 1, the first end side 161 is parallel to the X axis direction. The second end side 162 is parallel to the Y axis direction. In addition, the Z axis is perpendicular to the upper surface of the semiconductor layer 105. In addition, the first end sides 161 are perpendicular to an extending direction or a longitudinal direction of a gate trench portion which will be described below. The second end sides 162 are parallel to the extending direction or the longitudinal direction of the gate trench portion which will be described below.

The semiconductor layer 105 is provided with an active portion 160. The active portion 160 is a region where a main current flows in the depth direction between the upper surface and a lower surface of the semiconductor layer 105 when the semiconductor apparatus 100 operates. An emitter electrode pad or the like is provided above the active portion 160, but is omitted in FIG. 1.

In the present example, the active portion 160 is provided with a transistor portion 70 including a transistor element such as an IGBT. In another example, a diode portion including a diode device such as a transistor portion 70 and FWD (Free Wheel Diode) may be alternately arranged along a predetermined array direction on the front surface of the semiconductor substrate 10. Although one transistor portion 70 is provided in the present example, a plurality of transistor portions 70 may also be provided. A well region of a P+ type or a gate runner may be provided between the transistor portions 70.

The transistor portion 70 has the collector region of the P+ type in a region in contact with the lower surface of the semiconductor layer 105. Also, the transistor portion 70 has front surface MOS structures periodically arranged on the upper surface side of the semiconductor layer 105, each of which has an emitter region of an N+ type, a base region of a P− type, a drift region of an N− type, a gate conductive portion, and a gate dielectric film.

The semiconductor apparatus 100 may have one or more pads above the semiconductor layer 105. The semiconductor apparatus 100 in this example has a gate pad 164. The semiconductor apparatus 100 may have a pad such as an anode pad, a cathode pad, and a current detection pad. Each pad is disposed in the vicinity of the first end side 161. The vicinity of the first end side 161 refers to a region between the first end side 161 and the emitter electrode in a top view. When the semiconductor apparatus 100 is mounted, each pad may be connected to an external circuit via a wiring line such as a wire.

A gate potential is applied to the gate pad 164. The gate pad 164 is electrically connected to a conductive portion of a gate trench portion of the active portion 160. The semiconductor apparatus 100 includes a gate runner 130 that connects the gate pad 164 and the gate trench portion. In FIG. 1, the gate runner 130 is hatched with diagonal lines.

The gate runner 130 is arranged between the active portion 160 and the first end side 161 or the second end side 162 in a top view. The gate runner 130 in the present example encloses the active portion 160 in a top view. A region enclosed by the gate runner 130 in a top view may be the active portion 160. In addition, the gate runner 130 is connected to the gate pad 164. The gate runner 130 is arranged above the semiconductor substrate 10. The gate runner 130 may be a metal wiring including aluminum or the like. The gate runner 130 may be provided separate from the emitter electrode.

A P type outer circumferential well region 11 is provided so as to overlap the gate runner 130. That is, similar to the gate runner 130, the P type outer circumferential well region 11 surrounds the active portion 160 in a top view. The P type outer circumferential well region 11 is provided so as to extend with a predetermined width also in a range not overlapping the gate runner 130. The P type outer circumferential well region 11 is a region of the second conductivity type. The P type outer circumferential well region 11 of the present example is of the P+ type.

The semiconductor apparatus 100 may include a temperature sensing portion (not shown) which is a PN junction diode formed of polysilicon or the like, and a current detection portion (not shown) which simulates an operation of a transistor portion 70 provided in the active portion 160. The temperature sensing portion may be connected to the anode pad and the cathode pad via a wiring. When the temperature sensing portion is provided, it is preferably provided at the center in the semiconductor layer 105 in the X axis direction and the Y axis direction.

The semiconductor apparatus 100 of the present example includes an edge termination structure portion 90 between the active portion 160 and the first end side 161 or the second end side 162 in a top view. The edge termination structure portion 90 of the present example is disposed between the outer circumferential gate runner 130 and the first end side 161 or the second end side 162. The edge termination structure portion 90 reduces electric field strength on a front surface side of the semiconductor substrate 10. The edge termination structure portion 90 may include at least one of a guard ring, a field plate, and a RESURF which are annularly provided to enclose the active portion 160.

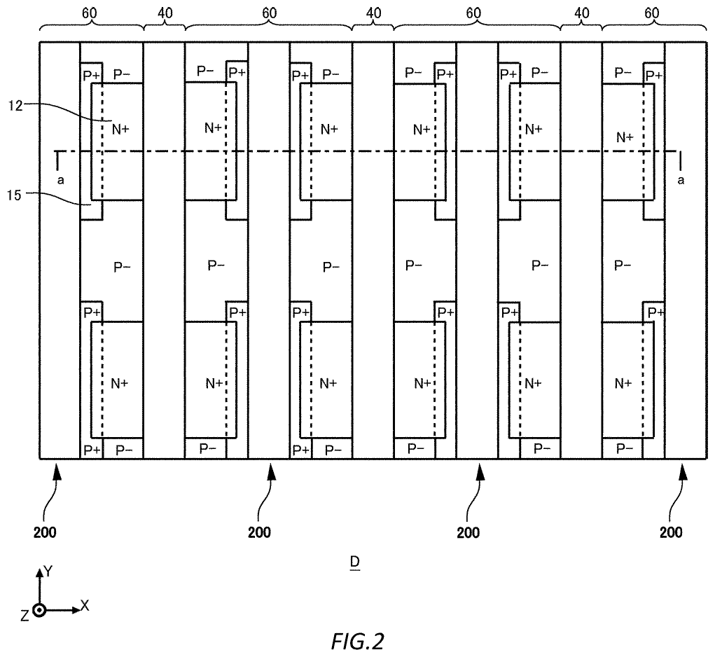

FIG. 2 is an example of an enlarged view of a region D in FIG. 1. The region D is a region which includes the transistor portion 70 of the active portion 160 shown in FIG. 1. In FIG. 2, a structure on the upper surface of the semiconductor layer 105 in the region D is shown. An interlayer dielectric film 38 and an emitter electrode 52 are provided above the upper surface of the semiconductor layer 105, but are omitted in FIG. 2. The semiconductor apparatus 100 of the present example comprises one or more gate trench portions 40, one or more emitter regions 12, and one or more contact regions 15. In another example, the semiconductor apparatus 100 may further comprise one or more dummy trench portions adjacent to the gate trench portions 40. In the present specification, the gate trench portion 40 may be simply referred to as a trench portion. In the present specification, when simply referred to as a trench portion, the trench portion may be the gate trench portion 40 or may be the dummy trench portion.

The gate trench portion 40 has a longitudinal length in a first direction on the upper surface of the semiconductor layer 105. In the present example, the gate trench portion 40 is provided to extend in the Y axis direction which is the first direction. The gate trench portion 40 is provided from the upper surface of the semiconductor layer 105 to the inside of the semiconductor layer 105. A gate conductive portion formed of a conductive material such as polysilicon is arranged inside the gate trench portion 40. The gate conductive portion is electrically connected to the gate runner 130 (see FIG. 1), and a predetermined gate voltage is applied thereto.

A plurality of trench portions are arrayed at predetermined intervals in a second direction intersecting with the first direction. The second direction in the present example is the X axis direction orthogonal to the first direction (the Y axis direction). In the present example, the dummy trench portion is not provided, the trench portion adjacent to the gate trench portion 40 in the X axis direction is the gate trench portion 40. In another example, the dummy trench portion is provided, and the trench portion adjacent to the dummy trench portion in the X axis direction may be the gate trench portion 40 or may be the dummy trench portion. In the X axis direction, one or more dummy trench portions may be arranged between two gate trench portions 40.

A region that is sandwiched between two trench portions in the X axis direction and that is of the semiconductor substrate 10 is defined as a mesa portion 60. Each end of the mesa portion 60 in the X axis direction is a boundary portion with each trench portion. A depth position of a lower end of the mesa portion 60 is to be the same as a depth position of a lower end of at least one of the trench portions on both sides.

The emitter region 12 is a region of a first conductivity type provided to be exposed on the upper surface of the semiconductor layer 105. As an example, the first conductivity type is an N type. The emitter region 12 is in contact with the gate trench portion 40. The emitter region 12 may be provided in each mesa portion 60 that is in contact with the gate trench portion 40. Each emitter region 12 may be band-shaped to have a longitudinal length in the Y axis direction in a top view. Due to each emitter region 12 having the longitudinal length in the Y axis direction, a length of a channel formed below the emitter region 12 in the Y axis direction can be increased and a channel density can be improved.

As shown in FIG. 2, in one mesa portion 60, a plurality of emitter regions 12 may be discretely arranged in the Y axis direction. In the Y axis direction, the distance between adjacent two emitter regions 12 may be less than the length of one emitter region 12, may be half or less, may be ¼ or less, or may be 1/10 or less of the length of one emitter region 12. In another example, only one emitter region 12 may be continuously arranged in one mesa portion 60 in the Y axis direction. In this case, the length of the emitter region 12 may be half or more or may be ¾ or more of the length of the mesa portion 60 in the Y axis direction.

The contact region 15 is a region of a second conductivity type exposed on the front surface of the semiconductor substrate 10 in the mesa portion 60 and connected to the emitter electrode. As an example, the second conductivity type is a P type. The contact region 15 of the present example is a region of a P+ type having a doping concentration higher than that of a base region described below. Due to the contact region 15 having the doping concentration higher than that of the base region, a contact resistance between the contact region 15 and the emitter electrode can be reduced.

As shown in FIG. 2, in one mesa portion 60, a plurality of contact regions 15 may be discretely arranged in the Y axis direction. The contact region 15 is provided to be in contact with a side surface and a bottom surface of a trench contact portion 200 described below. Each contact region 15 may be band-shaped to have a longitudinal length in the Y axis direction in a top view. In a top view of the semiconductor substrate 10, the contact region 15 may be arranged to overlap with the emitter region 12. In FIG. 2, end portions of the contact regions 15 arranged below the emitter regions 12 are shown with dashed lines. In the Y axis direction, a length of one the contact region 15 may be greater than a length of one emitter region 12. In this way, a contact area between the contact region 15 and the emitter electrode can be increased.

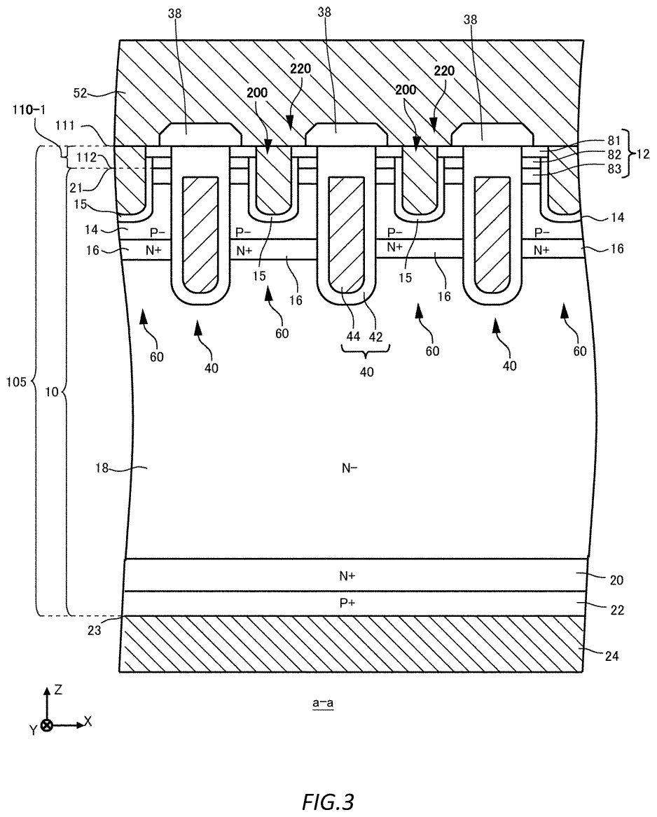

FIG. 3 illustrates one example of a cross section taken along a line a-a in FIG. 2. The cross section taken along a-a is an X-Z cross section passing through the emitter region 12 and the contact region 15. The semiconductor apparatus 100 of this example has the semiconductor layer 105, an interlayer dielectric film 38, the emitter electrode 52, and a collector electrode 24, in the cross section.

The semiconductor layer 105 of the present example comprises a semiconductor substrate 10, and an additional layer 110 provided on a front surface 21 of the semiconductor substrate 10. The additional layer 110 of the present example is an epitaxial layer 110-1. The upper surface of the semiconductor layer 105 of the present example is an upper surface 111 of the additional layer 110, and the lower surface of the semiconductor layer 105 is a back surface 23 of the semiconductor substrate 10. The lower surface of the additional layer 110 is in contact with the front surface 21 of the semiconductor substrate 10.

The emitter electrode 52 of the present example is provided above the upper surface 111 of the additional layer 110. A part of the upper surface 111 of the additional layer 110 is covered with the interlayer dielectric film 38. The emitter electrode 52 contacts at least a part of the upper surface 111 of the additional layer 110 that is not covered with the interlayer dielectric film 38. The emitter electrode 52 of the present example is in contact with the contact region 15.

The emitter electrode 52 is formed of a material including a metal. For example, at least a part of a region of the emitter electrode 52 is formed of aluminum or an aluminum-silicon alloy, for example, a metal alloy such as AlSi, AlSiCu. The emitter electrode 52 may have a barrier metal formed of titanium, titanium nitride, or the like below a region formed of aluminum or the like. The barrier metal may be in contact with the semiconductor substrate 10. The emitter electrode 52 may have a metal plug formed of tungsten or the like below the region formed of aluminum or the like.

The collector electrode 24 is provided on the back surface 23 of the semiconductor substrate 10. In the present specification in which, the collector electrode 24 may be formed, similar to the emitter electrode 52, with a metal material such as aluminum, or may be formed by stacking a plurality of different metal materials, a direction which connects the emitter electrode 52 and the collector electrode 24 (a Z axis direction) is referred to as a depth direction.

The interlayer dielectric film 38 is provided on the upper surface 111 of the additional layer 110. The interlayer dielectric film 38 is a film including at least one layer of a dielectric film such as silicate glass to which an impurity such as boron or phosphorous is added, a thermal oxide film, and other dielectric films. The interlayer dielectric film 38 may cover each trench portion.

The interlayer dielectric film 38 of the present example has a plurality of contact holes 220. The contact hole 220 is provided, above the mesa portion 60, between the emitter electrode 52 and the upper surface 111 of the additional layer 110. The emitter electrode 52 is electrically connected to the upper surface 111 of the additional layer 110 by the contact hole 220. The emitter electrode 52 is filled in the contact hole 220. The emitter electrode 52 may have a plug formed of tungsten or the like in the contact hole 220. The plug may form a barrier metal on a side in contact with the additional layer 110 in the contact hole 220, and may be formed by embedding tungsten to be in contact with the barrier metal.

In each mesa portion 60, a base region 14 of a P− type is provided in the semiconductor substrate 10. The base region 14 is in contact with the gate trench portion 40. The base region 14 may be in contact with each of trench portions on both sides of the mesa portion 60. At least part of the base region 14 is provided below the emitter region 12. The base region 14 may be in contact with the emitter region 12. When a predetermined ON voltage is applied to the gate trench portion 40, a surface layer of the base region 14 in contact with the gate trench portion 40 is inverted to a region of the N type to form a channel. The emitter region 12 is electrically connected by the channel to a drift region 18 which will be described below.

The base region 14 is provided also below the contact region 15. The base region 14 is in contact with the contact region 15. The base region 14 in the present example is a region of the P− type having a lower doping concentration than the contact region 15.

The semiconductor substrate 10 includes an N− type drift region 18. The emitter region 12 has a higher doping concentration than the drift region 18. The drift region 18 is provided below the base region 14. The semiconductor substrate 10 may or may not have, between the drift region 18 and the base region 14, an accumulation region 16 of an N+ type having a higher doping concentration than that of the drift region 18. Providing the accumulation region 16 can produce an electron injection enhancement effect to reduce an ON voltage of the semiconductor apparatus 100.

A collector region 22 of a P+ type is provided between the drift region 18 and the back surface 23 of the semiconductor substrate 10. A doping concentration of the collector region 22 is higher than a doping concentration of the base region 14. The collector region 22 may include an acceptor which is the same as or different from an acceptor of the base region 14. The acceptor of the collector region 22 is, for example, boron. The element serving as the acceptor is not limited to the example described above. The collector region 22 is exposed on the back surface 23 of the semiconductor substrate 10 and are connected to the collector electrode 24. The collector electrode 24 may be in contact with the entire back surface 23 of the semiconductor substrate 10.

The semiconductor substrate 10 may have a buffer region 20 of an N+type between the drift region 18 and the collector region 22. A doping concentration of the buffer region 20 is higher than the doping concentration of the drift region 18. The buffer region 20 may have one or more concentration peaks with a higher doping concentration than that of the drift region 18. The doping concentration of the concentration peak refers to a doping concentration at the local maximum of the concentration peak. In addition, as the doping concentration of the drift region 18, an average value of doping concentrations in the region where the doping concentration distribution is substantially flat may be used.

The buffer region 20 may be formed by ion implantation of the dopant of the N type such as hydrogen (proton) or phosphorous. The buffer region 20 of the present example is formed by the ion implantation of hydrogen. The buffer region 20 may function as a field stopper layer which prevents a depletion layer expanding from a lower end of the base region 14 from reaching the collector region 22.

One or more gate trench portions 40 are provided on the upper surface 111 of the additional layer 110. In the present example, a plurality of gate trench portions 40 are provided on the upper surface 111 of the additional layer 110. In the present example, each gate trench portion 40 penetrates the base region 14 from the upper surface 111 of the additional layer 110 to reach the drift region 18. The configuration of the trench portion penetrating the doping region is not limited to the one manufactured in the order of forming the doping region and then forming the trench portion. The configuration of the trench portion penetrating the doping region includes a configuration of the doping region being formed between the trench portions after forming the trench portion.

Each gate trench portion 40 has a gate trench having a groove shape that is provided in the upper surface 111 of the additional layer 110, a gate dielectric film 42 and a gate conductive portion 44. The gate conductive portion 44 is formed of polysilicon as a conductive material. The gate dielectric film 42 is provided to cover an inner wall of the gate trench. The gate dielectric film 42 may be formed by oxidizing or nitriding a semiconductor on the inner wall of the gate trench. The gate conductive portion 44 is provided on an inner side further than the gate dielectric film 42 in the gate trench. In other words, the gate dielectric film 42 insulates the gate conductive portion 44 from the semiconductor substrate 10.

The gate conductive portion 44 in the gate trench portion 40 may be provided longer than the base region 14 in the depth direction. The gate trench portion 40 in the cross section is covered by the interlayer dielectric film 38 on the upper surface 111 of the additional layer 110. The gate conductive portion 44 is electrically connected to the gate runner 130 at a position other than the cross section shown in FIG. 3.

In another example, a dummy trench portion having a structure similar to that of the gate trench portion 40 may be provided. The dummy trench portion may have a dummy trench of a groove shape, a dummy insulating film, and a dummy conductive portion having a structure similar to that of the gate trench, the gate dielectric film 42 and the gate conductive portion 44. The dummy conductive portion may be electrically connected to the emitter electrode 52.

The semiconductor apparatus 100 of the present example comprises a trench contact portion 200 below the contact hole 220. The trench contact portion 200 is a concave portion formed from the upper surface 111 of the additional layer 110 to the inside of the semiconductor substrate 10. The trench contact portion 200 of the present example is provided from the upper surface 111 of the additional layer 110 to a position deeper than the upper end of the base region 14. Inside the trench contact portion 200, similar to the contact hole 220, the emitter electrode 52 is filled. The trench contact portion 200 may include tungsten. In the side surface and the bottom surface of the trench contact portion 200, the emitter electrode 52 and the semiconductor layer 105 contact. In this way, the contact area of the emitter electrode 52 and the semiconductor layer 105 can be increased.

In another example, the trench contact portion 200 may be provided above the dummy trench portion. Above the dummy trench portion, one or more trench contact portions 200 may be provided. Alternatively, above one dummy trench portion, one trench contact portion 200 having a width wider than that of the dummy trench portion in the X axis direction may be provided. Due to such a structure, even if the mesa portion 60 between the trench portions is miniaturized, the trench contact portion 200 can be easily provided.

The side surface and the bottom surface of the trench contact portion 200 of the present example is in contact with the contact region 15. That is, the side surface of the trench contact portion 200 may be covered with the contact region 15 except for a portion in contact with the contact emitter portion 81 described below. In this way, since a hole current that flows toward the upper surface 111 of the additional layer 110 can be extracted, latch-up can be suppressed.

In FIG. 3, the side surface of the trench contact portion 200 may be tilted, although it is shown as perpendicular with respect to the upper surface 111 of the additional layer 110. Also, the bottom surface of the trench contact portion 200 may be flat, although it is shown to have a shape that curves downwards. The side surface and the bottom surface of the trench contact portion 200 are merely distinguished for convenience, a portion in which an outer surface of the trench contact portion 200 extends in the depth direction from the upper surface 111 of the additional layer 110 may be referred to as a side surface, and a portion having a different extending direction from the side surface and that connects side surfaces may be referred to as a bottom surface.

The emitter region 12 of the present example has a contact emitter portion 81 of an N+ type and a resistance emitter portion 82 of an N type. The emitter region 12 may further have an additional emitter portion 83 of the N+ type. The contact emitter portion 81 and the resistance emitter portion 82 of the present example are provided in the additional layer 115, and the additional emitter portion 83 is provided in the semiconductor substrate 10.

The contact emitter portion 81 is provided to be in contact with the upper surface 111 of the additional layer 110. The contact emitter portion 81 of the present example is provided above the resistance emitter portion 82. The contact emitter portion 81 of the present example is provided to be in contact with the side surface of the gate trench portion 40. The contact emitter portion 81 of the present example is provided to be extended from the gate trench portion 40 to the trench contact portion 200 of an adjacent mesa portion 60 in the X axis direction.

The resistance emitter portion 82 is provided to be in contact with the contact emitter portion 81. The resistance emitter portion 82 is a region of the N type having a lower doping concentration than that of the contact emitter portion 81. The resistance emitter portion 82 of the present example is provided below the contact emitter portion 81. In another example, the resistance emitter portion 82 may be provided on the upper surface 111 of the additional layer 110 to be adjacent to the contact emitter portion 81.

The resistance emitter portion 82 of the present example is provided to be in contact with the side surface of the gate trench portion 40. Unlike the contact emitter portion 81, the resistance emitter portion 82 of the present example is provided to be spaced apart from the trench contact portion 200.

A thickness of the semiconductor substrate 10 of the resistance emitter portion 82 of the present example in the depth direction is 0.1μm or more and 0.4 μm or less. A width of the resistance emitter portion 82 of the present example in the X axis direction is less than the width of the contact emitter portion 81 in the X axis direction. The width X2 of the resistance emitter portion 82 of the present example in the X axis direction is 0.2 μm or more and 2 μm or less.

The resistance emitter portion 82 of the present example has a lower doping concentration than that of the contact emitter portion 81. The doping concentration of the resistance emitter portion 82 of the present example is 1E13 cm⁻³ or more and 1E15 cm⁻³ or less. In this way, the resistance value of the resistance emitter portion 82 increases. Also, a current flowing between the contact emitter portion 81 and the base region 14 passes through the resistance emitter portion 82. Thus, the resistance emitter portion 82 of the present example functions as a resistance portion, and can suppress a saturation current flowing in a MOS structure. In addition, by providing the emitter region 12 having a longitudinal length in the Y axis direction, a total emitter width in the Y axis direction is increased, and an ON voltage is decreased. In this manner, by providing the resistance emitter portion 82 that functions as the resistance portion, both a low saturation current and a low ON voltage can be achieved.

The additional emitter portion 83 is provided to be in contact with the resistance emitter portion 82 below the resistance emitter portion 82. The additional emitter portion 83 is a region of the N+ type having a higher doping concentration than that of the resistance emitter portion 82. The additional emitter portion 83 may have a lower doping concentration than that of the contact emitter portion 81. The additional emitter portion 83 of the present example is provided to be in contact with the side surface of the gate trench portion 40. Similar to the resistance emitter portion 82, the additional emitter portion 83 of the present example is provided to be spaced apart from the trench contact portion 200. The additional emitter portion 83 of the present example is provided in the semiconductor substrate 10, but in another example, the additional emitter portion 83 may be provided on the additional layer 110.

In the depth direction of the semiconductor substrate 10, an upper end of the gate conductive portion 44 of the gate trench portion 40 is arranged to be opposite to the additional emitter portion 83. The upper end of the gate conductive portion 44 may refer to an upper end on a side surface opposite to the mesa portion 60. The upper end of the gate conductive portion 44 and the additional emitter portion 83 being opposite to each other means that the upper end of the gate conductive portion 44 is arranged between an upper end position and a lower end position of the additional emitter portion 83 in the Z axis direction. The upper end and the lower end of the additional emitter portion 83 may refer to an upper end and a lower end in a portion in contact with the side surface of the gate trench portion 40.

Once an ON voltage is applied to the gate conductive portion 44, an electron is attracted to a region opposite to the gate conductive portion 44 among a boundary portion with the trench portion in the mesa portion 60. When the resistance emitter portion 82 and the gate conductive portion 44 are arranged to be opposite to each other, electrons are attracted to a boundary portion of the resistance emitter portion 82. Since a doping concentration of the resistance emitter portion 82 is low, due to the electrons that are attracted, a resistance value in the boundary portion may vary. Meanwhile, by arranging the additional emitter portion 83 to be opposite to the upper end of the gate conductive portion 44, the variation of the resistance value in the boundary portion of the resistance emitter portion 82 can be suppressed. Also, since a doping concentration of the additional emitter portion 83 is high, even if the electrons are attracted to the boundary portion of the additional emitter portion 83, a variation of the resistance value of the boundary portion is very small.

The contact emitter portion 81 of the present example is in contact with the trench contact portion 200. In this way, the connect resistance between the emitter electrode 52 and the contact emitter portion 81 can be reduced. The contact emitter portion 81 may be in contact with the upper end of the contact region 15 on the side surface of the trench contact portion 200.

The resistance emitter portion 82 of the present example is provided to be spaced apart from the trench contact portion 200. A contact region 15 is provided between the resistance emitter portion 82 and the trench contact portion 200 of the present example. The resistance emitter portion 82 of the present example is provided to be in contact with the contact region 15 provided on the side surface of the trench contact portion 200. Due to such a configuration, a current is prevented from flowing between the emitter electrode 52 and the resistance emitter portion 82 through a path other than the contact emitter portion 81. In another example, a trench insulating film is provided on the side surface and the bottom surface of the trench contact portion 200, and the resistance emitter portion 82 may be provided to be in contact with the trench insulating film provided on the side surface of the trench contact portion 200.

The contact emitter portion 81 and the resistance emitter portion 82 of the present example are provided on the additional layer 110. The additional layer 110 of the present example is an epitaxial layer 110-1 that is epitaxially grown on the front surface 21 of the semiconductor substrate 10 after a doping region such as an additional emitter portion 83, a base region 14, an accumulation region 16 is formed on a front surface 21 side of the semiconductor substrate 10 by ion implantation. The contact emitter portion 81 of the present example is formed by performing laser annealing after the ion implantation of phosphorous, arsenic or the like from the upper surface 111 of the additional layer 110. The doping concentration of the contact emitter portion 81 of the present example is 3E19 cm⁻³ or more and 5E19 cm⁻³ or less.

The resistance emitter portion 82 may be a region below the contact emitter portion 81 that remains in the additional layer 110 without the ion implantation. The doping concentration of the resistance emitter portion 82 may be the same as the doping concentration at the time of forming the epitaxial layer 110-1, and may be 1E13 cm⁻³ or more and 1E15 cm⁻³ or less. In order to adjust the doping concentration of the resistance emitter portion 82, phosphorous, arsenic or the like may be ion implanted from the upper surface 111 of the additional layer 110.

Upon forming a resistance emitter portion 82 with a low doping concentration between a contact emitter portion 81 with a high doping concentration and the additional emitter portion 83, since an ion that is implanted is thermally diffused, it is difficult to suppress the doping concentration of the resistance emitter portion 82 to be low and there is a risk of variation. In the present example, since the resistance emitter portion 82 is formed by utilizing the doping concentration of the epitaxial layer 110-1 provided as the additional layer 110 on the front surface 21 of the semiconductor substrate 10, a resistance emitter portion 82 with low doping concentration and less doping concentration variation can be formed. In this manner, according to the present example, the resistance emitter portion 82 with high resistance can be stably formed, and both a low saturation current and a low ON voltage can be achieved.

The additional emitter portion 83 of the present example is provided to be spaced apart from the trench contact portion 200. A contact region 15 is provided between the additional emitter portion 83 and the trench contact portion 200 of the present example. The additional emitter portion 83 of the present example is provided to be in contact with the contact region 15 provided on the side surface of the trench contact portion 200. By such a configuration, a current that has passed through a channel of the base region 14 is prevented from passing through the emitter electrode 52 without passing through the resistance emitter portion 82. In another example, a trench insulating film is provided on the side surface and the bottom surface of the trench contact portion 200, and the additional emitter portion 83 may be provided to be in contact with the trench insulating film provided on the side surface of the trench contact portion 200.

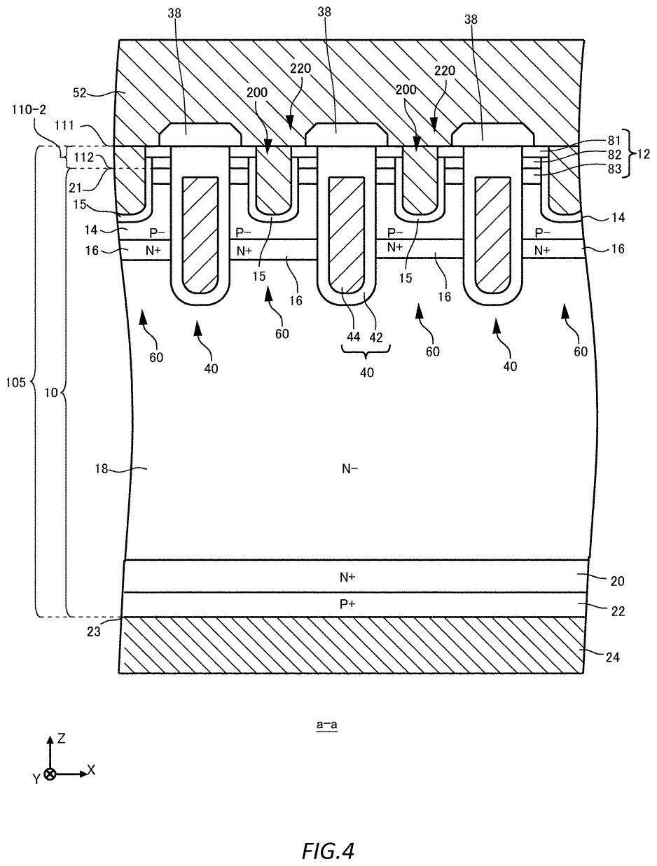

FIG. 4 illustrates another example of a cross section taken along a line a-a in FIG. 2. The additional layer 110 of the present example is different from that of FIG. 3 in that it is a polysilicon layer 110-2. Descriptions of the other components are omitted herein since they are common with those of FIG. 3.

A polysilicon layer 110-2 has a high temperature dependency, and its resistance increases as its temperature increases by the heat generation of the device. Therefore, since the resistance of the resistance emitter portion 82 increases as an ON voltage is applied to the gate trench portion 40, the current is suppressed. In this manner, according to the present example, both a low saturation current and a low ON voltage can be achieved without requiring adjusting the doping concentration of the resistance emitter portion 82 to be dense.

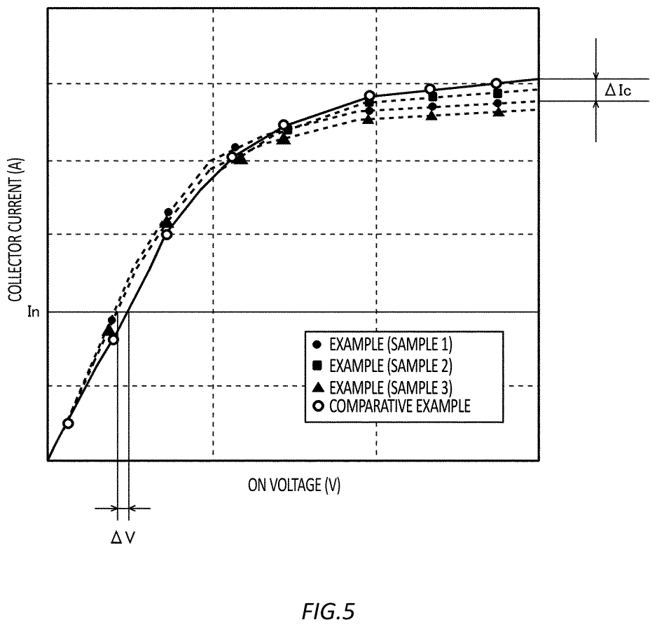

FIG. 5 is an example of an I-V curve that indicates a relationship between a collector current and an ON voltage. In FIG. 5, the horizontal axis shows an ON voltage (V), and the vertical axis shows a collector current (A). The I-V curves indicated with the dashed lines show samples 1 to 3 in the examples, and an I-V curve indicated with a solid line shows a sample of a comparative example. An emitter region of a semiconductor apparatus according to the comparative example only has a contact emitter portion 81 and does not have a resistance emitter portion 82. Herein, the I-V curves are compared under an environment in which a saturation current of each sample is equivalent.

If an ON voltage is applied to the gate trench portion 40, the collector current increases to reach the saturation current. First, comparing ON voltages when the collector current reached a rated current In, an ON voltage of the sample 1 of the example is less than an ON voltage of the comparative example by a voltage difference ΔV. ON voltages of other samples 2 and 3 of the example are less than the ON voltage of the comparative example. That is, the I-V curve of the example rises faster than the I-V curve of the comparative example, and the ON voltage decreases.

Then, comparing the saturation currents, a saturation current of the sample 1 of the example is less than a saturation current of the comparative example by a current difference ΔIc. Saturation currents of other samples 2 and 3 of the example are less than the saturation current of the comparative example. That is, the I-V curve of the example has a peak lower than that of the I-V curve of the comparative example, and the saturation current is suppressed.

If the I-V curve rises faster, the ON voltage decreases, but the collector current increases faster and therefore there is a risk of increasing saturation current. However, according to the example, the saturation current can be suppressed since after the emitter region 12 is electrically conducted by applying the ON voltage to the gate conductive portion 44, an electron moving from the contact emitter portion 81 toward a channel is limited at the resistance emitter portion 82 of a high resistance, and an injection amount of the electron becomes stable. In this manner, by providing the resistance emitter portion 82, both a low saturation current and a low ON voltage can be achieved. Also, by providing the resistance emitter portion 82, the injection amount of the electron is stably limited to a constant current, and therefore the variation of the current decreases, and a short circuit withstand capability that is approximately the same as that of the comparative example can be secured. Furthermore, according to the example, by providing the resistance emitter portion 82 in the additional layer 110, a resistance emitter portion 82 with a low doping concentration and a high resistance can be stably formed.

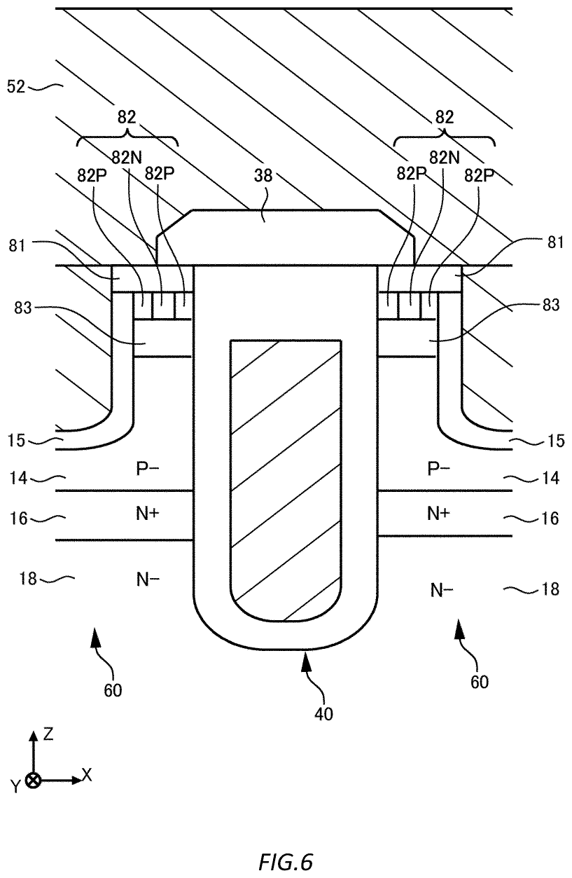

FIG. 6 illustrates another example of a cross section taken along a line a-a in FIG. 2. FIG. 6 shows an enlarged view of an X-Z cross section taken through a gate trench portion 40 and an adjacent mesa portion 60. A resistance emitter portion 82 of the present example includes a JFET configuration. The JFET configuration of the present example has a first conductivity type region 82N, and a second conductivity type region 82P provided on both ends of the first conductivity type region 82N in the X axis direction.

The first conductivity type region 82N of the present example is a region of an N type. A doping concentration of the first conductivity type region 82N of the present example may be the same as the doping concentration of an additional emitter portion 83, and 1E13 cm⁻³ or more and 1E17 cm⁻³ or less.

The second conductivity type region 82P of the present example is a region of a P type with a higher doping concentration than that of the base region 14. A doping concentration of the second conductivity type region 82P of the present example is 1E13 cm⁻³ or more and 1E18 cm⁻³ or less. The second conductivity type region 82P may be formed by performing a high acceleration ion implantation of boron from the upper surface 111 of the additional layer 110.

In the X axis direction, the second conductivity type region 82P between the first conductivity type region 82N and a gate dielectric film 42 may be provided to be in contact with the gate dielectric film 42, and the second conductivity type region 82P between the first conductivity type region 82N and a contact region 15 may be provided to be in contact with the contact region 15.

If an ON voltage is applied to the gate trench portion 40, a depletion layer is formed by a PN coupling between the first conductivity type region 82N and the second conductivity type region 82P, and a movement path of electrons are limited only between depletion layers formed on both ends of the first conductivity type region 82N. In this manner, the resistance emitter portion 82 of the present example functions as a resistor, and an injection amount of the electrons can be adjusted by adjusting intervals between the depletion layers without requiring adjusting the doping concentration.

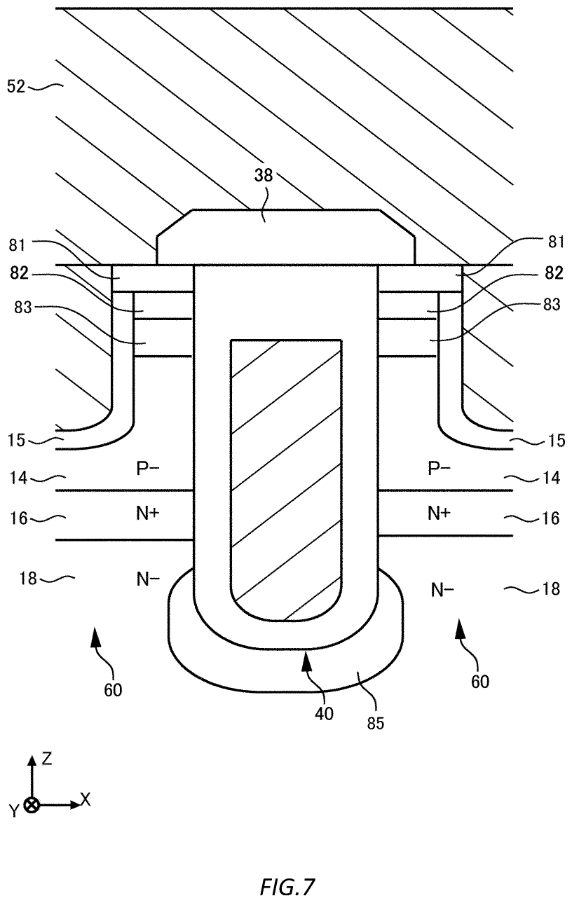

FIG. 7 illustrates another example of a cross section taken along a line a-a in FIG. 2. FIG. 7 shows an enlarged view of an X-Z cross section taken through a gate trench portion 40 and an adjacent mesa portion 60. At a lower end of the gate trench portion 40 of the present example, a second conductivity type region 85 is provided. The second conductivity type region 85 of the present example is provided below the accumulation region 16. In a depth direction of a semiconductor substrate 10, a lower end of the second conductivity type region 85 may be positioned below the lower end of the gate trench portion 40. In other words, the second conductivity type region 85 may cover the lower end of the gate trench portion 40. A doping concentration of the second conductivity type region 85 may be higher than a doping concentration of the drift region 18 and may be lower than a doping concentration of the base region 14.

By providing the second conductivity type region 85, a turn-on characteristic of a transistor portion 70 is improved. Also, by providing the second conductivity type region 85, an electric field strength at the lower end of the gate trench portion 40 is relaxed, and an avalanche capability is improved.

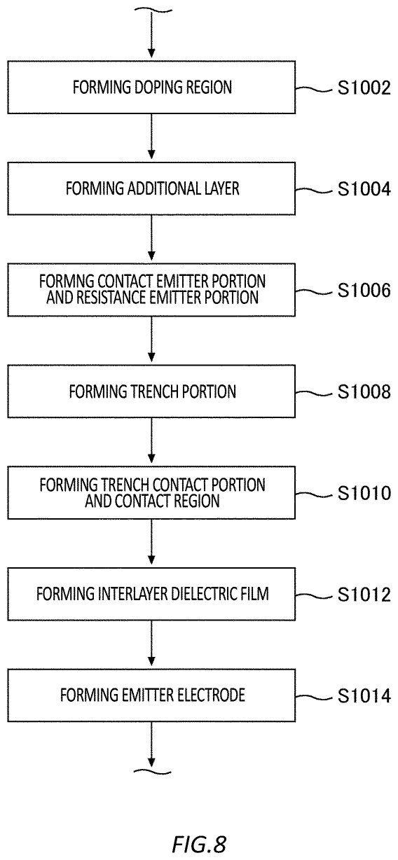

FIG. 8 illustrates some steps in a fabrication method of the semiconductor apparatus 100. The fabrication method of the present example includes a doping region forming step S1002, an additional layer forming step S1004, a contact emitter portion and resistance emitter portion forming step S1006, a trench portion forming step S1008, a trench contact portion and contact region forming step S1010, an interlayer dielectric film forming step S1012 and an emitter electrode formation step S1014.

In the doping region forming step S1002, respective doping regions such as a drift region 18 and a base region 14 are formed by performing ion implantation of a dopant into the semiconductor substrate 10. The additional emitter portion 83 may be formed in this doping region forming step S1002.

Then, in the additional layer forming step S1004, an additional layer 110 is formed on a front surface 21 of the semiconductor substrate 10. The additional layer 110 may be an epitaxial layer 110-1 as in FIG. 3, or may be a polysilicon layer 110-2 as in FIG. 4. The additional layer 110 may have a doping concentration depending on the specification of a device.

Then, in the contact emitter portion and resistance emitter portion forming step S1006, a contact emitter portion 81 is formed on an upper surface 111 of the additional layer 110, and a resistance emitter portion 82 is formed above the contact emitter portion 81. The contact emitter portion 81 may be formed by performing ion implantation of a dopant such as phosphorous or arsenic from the upper surface 111 of the additional layer 110. After the ion implantation, by performing laser annealing the implanted ion may be thermally diffused, and the contact emitter portion 81 may be single-crystallized. A doping concentration of the contact emitter portion 81 may be 3E19 cm⁻³ or more and 5E19 cm⁻³ or less. The resistance emitter portion 82 may be a region below the contact emitter portion 81 that remains in the additional layer 110 without the ion implantation. A doping concentration of the resistance emitter portion 82 may be 1E13 cm⁻³ or more and 1E15 cm⁻³ or less. Note that the second conductivity type region 82P in FIG. 6 may be formed by performing a high acceleration ion implantation of boron from the upper surface 111 of the additional layer 110.

Then, in the trench portion forming step S1008, a gate trench portion 40 is formed on the upper surface 111 of the additional layer 110. The gate trench portion 40 may be formed by forming a gate trench having a groove shape on the upper surface 111 of the additional layer 110 by etching, depositing a gate dielectric film 42 by oxidizing or nitriding a semiconductor on an inner wall of the gate trench, forming a gate conductive portion 44 by depositing polysilicon that is a conductive material on a position closer to the inside than the gate dielectric film 42 inside the gate trench. The contact emitter portion 81, the resistance emitter portion 82, and the additional emitter portion 83 of the present example are in contact with the gate trench portion 40. Note that the second conductivity type region 85 in FIG. 7 may be formed by performing ion implantation of a dopant from the gate trench after forming the gate trench.

Then, in the trench contact portion and contact region forming step S1010, a trench contact portion 200 is formed on the upper surface 111 of the additional layer 110, and a contact region 15 is formed on a side surface and a bottom surface of the trench contact portion 200. The trench contact portion 200 may be formed from the upper surface 111 of the additional layer 110 to a position deeper than the upper end of the base region 14. The trench contact portion 200 may be formed by forming a trench having a groove shape on the upper surface 111 of the additional layer 110 by etching, forming a barrier metal on an inner wall of the trench, and embedding tungsten to be in contact with the barrier metal. The contact region 15 may be formed by performing a diagonal ion implantation of a dopant into the trench after forming the trench of the trench contact portion 200.

Then, in the interlayer dielectric film forming step S 1012 and emitter electrode formation step S1014, an interlayer dielectric film 38 is formed on the upper surface 111 of the additional layer 110, and an emitter electrode 52 is formed above the interlayer dielectric film 38. In the interlayer dielectric film forming step S1002, an dielectric film such as PSG may be deposited on the entire upper surface 111 of the additional layer 110.

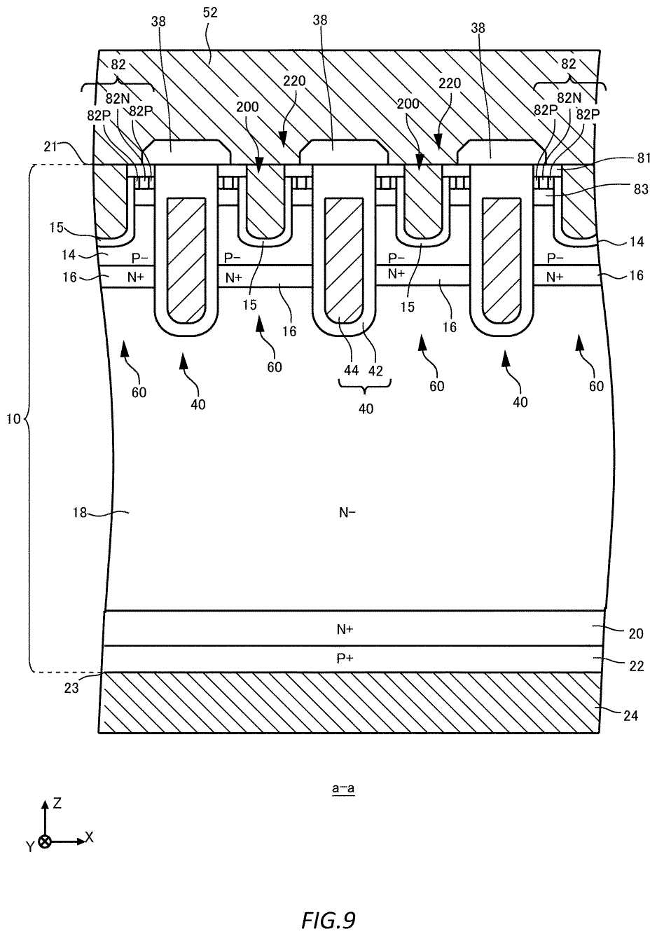

FIG. 9 illustrates variants of a cross section taken along a line a-a in FIG. 2. The semiconductor apparatus 100 of the present example is different from those of FIG. 3 and FIG. 4 in that it does not comprise the additional layer 110. The contact emitter portion 81 and the resistance emitter portion 82 of the present example are provided on a front surface 21 side of the semiconductor substrate 10. That is, the cross section taken along a-a of FIG. 9 sequentially passes through the contact emitter portion 81, the resistance emitter portion 82, the additional emitter portion 83, the base region 14, the accumulation region 16, and the drift region 18 from the front surface 21 of the semiconductor substrate 10 toward the depth direction.

The contact emitter portion 81 of the present example is provided on a front surface 21 side of the semiconductor substrate 10. The resistance emitter portion 82 of the present example is provided below the contact emitter portion 81, and the additional emitter portion 83 of the present example is provided below the resistance emitter portion 82.

A resistance emitter portion 82 of the present example includes a JFET configuration. The JFET configuration of the present example has a first conductivity type region 82N, and a second conductivity type region 82P provided on both ends of the first conductivity type region 82N in the X axis direction. That is,, the JFET configuration of the present example is the same as the JFET configuration in FIG. 6 except that it is provided in the semiconductor substrate 10. A doping concentration of the first conductivity type region 82N may be the same as the doping concentration of an additional emitter portion 83, and 1E13 cm⁻³ or more and 1E17 cm⁻³ or less. A doping concentration of the second conductivity type region 82P may be higher than the doping concentration of the base region 14, and 1E13 cm⁻³ or more and 1E18 cm⁻³ or less. The second conductivity type region 82P may be formed by performing a high acceleration ion implantation of boron from the front surface 21 of the semiconductor substrate 10.

In the X axis direction, the second conductivity type region 82P between the first conductivity type region 82N and a gate dielectric film 42 may be provided to be in contact with the gate dielectric film 42, and the second conductivity type region 82P between the first conductivity type region 82N and a contact region 15 may be provided to be in contact with the contact region 15. Also, in the present example, a second conductivity type region 85 may be provided on a lower end of the gate trench portion 40 as shown in FIG. 7.

If an ON voltage is applied to the gate trench portion 40, a depletion layer is formed by a PN coupling between the first conductivity type region 82N and the second conductivity type region 82P, and a movement path of electrons are limited only between depletion layers formed on both ends of the first conductivity type region 82N. In this manner, the resistance emitter portion 82 of the present example functions as a resistor, and an injection amount of the electrons can be adjusted by adjusting intervals between the depletion layers without requiring adjusting the doping concentration.

In this manner, in the present example, since the additional layer 110 may not be provided, a resistance emitter portion 82 with high resistance can be stably formed while simplifying the process, thereby both a low saturation current and a low ON voltage can be achieved.

While the present invention has been described by way of the embodiments, the technical scope of the present invention is not limited to the above-described embodiments. It is apparent to persons skilled in the art that various alterations or improvements can be made to the above-described embodiments. It is also apparent from the scope of the claims that the embodiments added with such alterations or improvements can be included in the technical scope of the present invention.

The operations, procedures, steps, stages, and the like of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

### (Item 1)

A semiconductor apparatus comprising a semiconductor substrate, and an additional layer provided on a front surface of the semiconductor substrate, wherein the semiconductor apparatus comprises:
a drift region of a first conductivity type provided in the semiconductor substrate;
a base region of a second conductivity type provided above the drift region in the semiconductor substrate;
a gate trench portion provided on an upper surface of the additional layer;
an emitter region of the first conductivity type that is provided above the base region and is in contact with the gate trench portion; and
a conductive trench contact portion provided from the upper surface of the additional layer to a position deeper than an upper end of the base region, wherein
the emitter region includes:
a contact emitter portion provided on the upper surface of the additional layer;
a resistance emitter portion provided in the additional layer; and
an additional emitter portion.

### (Item 2)

The semiconductor apparatus according to item 1, wherein the resistance emitter portion is provided to be spaced apart from the trench contact portion.

### (Item 3)

The semiconductor apparatus according to item 1, comprising a contact region of the second conductivity type provided to be in contact with a side surface of the trench contact portion and that has a higher doping concentration than that of the base region, wherein

the resistance emitter portion is provided to be in contact with the contact region.

### (Item 4)

The semiconductor apparatus according to item 1, comprising a trench insulating film provided to be in contact with a side surface of the trench contact portion, wherein

the resistance emitter portion is provided to be in contact with the trench insulating film.

### (Item 5)

The semiconductor apparatus according to item 1, wherein

a doping concentration of the resistance emitter portion is 1E13 cm⁻³ or more and 1E15 cm⁻³ or less.

### (Item 6)

The semiconductor apparatus according to item 1, wherein
the resistance emitter portion is provided below the contact emitter portion and has a lower doping concentration than that of the contact emitter portion.

### (Item 7)

The semiconductor apparatus according to item 1, wherein
the additional emitter portion is provided below the resistance emitter portion and has a higher doping concentration than that of the resistance emitter portion.

### (Item 8)

The semiconductor apparatus according to item 7, wherein
the gate trench portion includes a gate conductive portion and a gate dielectric film provided in a trench, and
an upper end of the gate conductive portion is arranged at a position opposite to the additional emitter portion in a depth direction of the semiconductor substrate.

### (Item 9)

The semiconductor apparatus according to item 1, wherein
the additional emitter portion is provided in the semiconductor substrate.

### (Item 10)

The semiconductor apparatus according to item 1, wherein
the contact emitter portion is provided above the resistance emitter portion.

### (Item 11)

The semiconductor apparatus according to item 1, wherein
the additional layer is an epitaxial layer.

### (Item 12)

The semiconductor apparatus according to item 1, wherein
the additional layer is a polysilicon layer.

### (Item 13)

The semiconductor apparatus according to item 1, wherein
the resistance emitter portion includes a JFET configuration.

### (Item 14)

The semiconductor apparatus according to item 13, wherein the JFET configuration includes:
a first conductivity type region; and
a second conductivity type region that is provided on both ends of the first conductivity type region in a trench array direction.

### (Item 15)

The semiconductor apparatus according to item 1, wherein
the semiconductor substrate includes either SiC or GaN.

### (Item 16)

A fabrication method of a semiconductor apparatus, comprising:
forming a drift region of a first conductivity type on a semiconductor substrate;
forming a base region of a second conductivity type above the drift region in the semiconductor substrate;
forming an additional layer on a front surface of the semiconductor substrate;
forming a gate trench portion on an upper surface of the additional layer;
forming, above the base region, an emitter region of the first conductivity type that is in contact with the gate trench portion; and
forming a conductive trench contact portion from the upper surface of the additional layer to a position deeper than an upper end of the base region, wherein
the forming the emitter region includes:
forming a contact emitter portion on the upper surface of the additional layer;
forming a resistance emitter portion in the additional layer; and
forming an additional emitter portion.

### (Item 17)

The fabrication method of semiconductor apparatus according to item 16, wherein
the forming the contact emitter portion includes performing ion implantation into the upper surface of the additional layer.

### (Item 18)

The fabrication method of semiconductor apparatus according to item 17, wherein
the forming the contact emitter portion includes performing laser annealing after the performing the ion implantation.

### (Item 19)

The fabrication method of semiconductor apparatus according to item 16, wherein
the forming the additional emitter portion includes performing ion implantation into the front surface of the semiconductor substrate.

### (Item 20)

The fabrication method of semiconductor apparatus according to item 16, wherein
the additional layer is an epitaxial layer.

### (Item 21)

The fabrication method of semiconductor apparatus according to item 16, wherein
the additional layer is a polysilicon layer.

### (Item 22)

A semiconductor apparatus, comprising:
a drift region of a first conductivity type provided in a semiconductor substrate;
a base region of a second conductivity type provided above the drift region;
a gate trench portion provided on a front surface of the semiconductor substrate;
an emitter region of the first conductivity type that is provided above the base region and is in contact with the gate trench portion; and
a conductive trench contact portion provided from the front surface of the semiconductor substrate to a position deeper than an upper end of the base region, wherein
the emitter region includes:
a contact emitter portion provided on the front surface of the semiconductor substrate;
a resistance emitter portion that is provided below the contact emitter portion and that includes a JFET configuration; and
an additional emitter portion provided below the resistance emitter portion.

### (Item 23)

The semiconductor apparatus according to item 22, wherein
the JFET configuration includes:
a first conductivity type region; and
a second conductivity type region provided on both ends of the first conductivity type region in a trench array direction.

### (Item 24)

The semiconductor apparatus according to item 23, wherein
a doping concentration of the first conductivity type region is the same as a doping concentration of the additional emitter portion.

### (Item 25)

The semiconductor apparatus according to item 23, wherein
a doping concentration of the second conductivity type region is higher than a doping concentration of the base region.

### EXPLANATION OF REFERENCES

10: semiconductor substrate
11: P type outer circumferential well region
12: emitter region
14: base region
15: contact region
16: accumulation region
18: drift region
20: buffer region
21: front surface
22: collector region
23: back surface
24: collector electrode
38: interlayer dielectric film
40: gate trench portion
42: gate dielectric film
44: gate conductive portion
52: emitter electrode
60: mesa portion
70: transistor portion
81: contact emitter portion
82: resistance emitter portion
82N: first conductivity type region
82P: second conductivity type region
83: additional emitter portion
85: second conductivity type region
90: edge termination structure portion
100: semiconductor apparatus
105: semiconductor layer
110: additional layer
110-1: epitaxial layer
110-2: polysilicon layer
111: upper surface
112: lower surface
115: additional layer
130: gate runner
140: gate trench portion
160: active portion
161: first end side
162: second end side
164: gate pad
200: trench contact portion
220: contact hole.

What is claimed is:

1. A semiconductor apparatus comprising a semiconductor substrate, and an additional layer provided on a front surface of the semiconductor substrate, wherein the semiconductor apparatus comprises:
a drift region of a first conductivity type provided in the semiconductor substrate;
a base region of a second conductivity type provided above the drift region in the semiconductor substrate;
a gate trench portion provided on an upper surface of the additional layer;
an emitter region of the first conductivity type that is provided above the base region and is in contact with the gate trench portion; and
a conductive trench contact portion provided from the upper surface of the additional layer to a position deeper than an upper end of the base region, wherein
the emitter region includes:
a contact emitter portion provided on the upper surface of the additional layer;
a resistance emitter portion provided in the additional layer; and
an additional emitter portion.

2. The semiconductor apparatus according to claim 1, wherein the resistance emitter portion is provided to be spaced apart from the trench contact portion.

3. The semiconductor apparatus according to claim 1, comprising a contact region of the second conductivity type provided to be in contact with a side surface of the trench contact portion and that has a higher doping concentration than that of the base region, wherein
the resistance emitter portion is provided to be in contact with the contact region.

4. The semiconductor apparatus according to claim 1, comprising a trench insulating film provided to be in contact with a side surface of the trench contact portion, wherein
the resistance emitter portion is provided to be in contact with the trench insulating film.

5. The semiconductor apparatus according to claim 1, wherein
a doping concentration of the resistance emitter portion is 1E13 cm⁻³ or more and 1E15 cm⁻³ or less.

6. The semiconductor apparatus according to claim 1, wherein
the resistance emitter portion is provided below the contact emitter portion and has a lower doping concentration than that of the contact emitter portion.

7. The semiconductor apparatus according to claim 1, wherein
the additional emitter portion is provided below the resistance emitter portion and has a higher doping concentration than that of the resistance emitter portion.

8. The semiconductor apparatus according to claim 7, wherein
the gate trench portion includes a gate conductive portion and a gate dielectric film provided in a trench, and
an upper end of the gate conductive portion is arranged at a position opposite to the additional emitter portion in a depth direction of the semiconductor substrate.

9. The semiconductor apparatus according to claim 1, wherein
the additional emitter portion is provided in the semiconductor substrate.

10. The semiconductor apparatus according to claim 1, wherein
the contact emitter portion is provided above the resistance emitter portion.

11. The semiconductor apparatus according to claim 1, wherein
the additional layer is an epitaxial layer.

12. The semiconductor apparatus according to claim 1, wherein
the additional layer is a polysilicon layer.

13. The semiconductor apparatus according to claim 1, wherein
the resistance emitter portion includes a JFET configuration.

14. The semiconductor apparatus according to claim 13, wherein the JFET configuration includes:
a first conductivity type region; and
a second conductivity type region that is provided on both ends of the first conductivity type region in a trench array direction.

15. The semiconductor apparatus according to claim 1, wherein
the semiconductor substrate includes either SiC or GaN.

16. A semiconductor apparatus, comprising:
a drift region of a first conductivity type provided in a semiconductor substrate;
a base region of a second conductivity type provided above the drift region;
a gate trench portion provided on a front surface of the semiconductor substrate;
an emitter region of the first conductivity type that is provided above the base region and is in contact with the gate trench portion; and
a conductive trench contact portion provided from the front surface of the semiconductor substrate to a position deeper than an upper end of the base region, wherein
the emitter region includes:
a contact emitter portion provided on the front surface of the semiconductor substrate;
a resistance emitter portion that is provided below the contact emitter portion and that includes a JFET configuration; and
an additional emitter portion provided below the resistance emitter portion.

17. The semiconductor apparatus according to claim 16, wherein
the JFET configuration includes:
a first conductivity type region; and
a second conductivity type region provided on both ends of the first conductivity type region in a trench array direction.

18. The semiconductor apparatus according to claim 17, wherein
a doping concentration of the first conductivity type region is the same as a doping concentration of the additional emitter portion.

19. The semiconductor apparatus according to claim 17, wherein
a doping concentration of the second conductivity type region is higher than a doping concentration of the base region.
